(19) United States
(12) Patent Application Publication
(10) Pub. No.: US 2008/0023756 A1
(43) Pub. Date: Jan. 31, 2008

(54) Semiconductor device and fabricating method thereof

(75) Inventor: Chang Myung Lee, Donghae-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/881,035

(22) Filed: Jul. 24, 2007

(30) Foreign Application Priority Data
Jul. 27, 2006 (KR) 10-2006-0070737

(51) Int. Cl. H01L 29/49; H01L 21/02

(52) U.S. Cl. 257/330; 438/270; 257/E21.2; 257/E29.156

(57) ABSTRACT

A semiconductor device and method of manufacturing the same. The semiconductor device includes a semiconductor substrate having a first conductive layer, a second conductive layer on the first conductive layer, a first high density impurity area on the second conductive layer, and a second high density impurity area on the first impurity area; a trench exposing the first conductive layer; a gate insulating layer on an inner wall of the trench; a polysilicon layer on the gate insulating layer; and a metal layer on the polysilicon layer in the trench, in which the metal layer fills the trench.

The present application claims priority under 35 U.S.C. 119 and 35 U.S.C. 365 to Korean Patent Application No. 10-2006-0070737 (filed on Jul. 27, 2006), which is hereby incorporated by reference in its entirety.

### BACKGROUND

As the manufacturing technology of a semiconductor device is developed and the application fields thereof are expanded, research and development have been continuously pursued to increase the integration degree of the semiconductor device. As a semiconductor device has become highly integrated and has been fabricated in a micro-size, the Critical Dimension (CD) of a gate electrode or a bit line of a Metal Oxide Semiconductor Field Effect Transistor (MOSFET) is also significantly decreased.

As described above, as the CD of the gate electrode is decreased, a surface resistance value of the gate electrode is increased. In order to reduce the resistance value of the gate electrode, there has been proposed a scheme for providing the gate electrode having a polycide structure including polysilicon and a metal silicide. However, such a scheme has a limitation in reducing the resistance of the gate electrode. For example, as the resistance of the gate electrode increases, a word line or gate driving speed of a MOSFET becomes slow, and the performance of the memory block/device or transistor deteriorates.

### SUMMARY

Embodiments of the invention provide a semiconductor device capable of improving a driving speed by decreasing a resistance value of a gate electrode in a highly integrated semiconductor device, and a fabricating method thereof.

In order to accomplish the object(s) of the present invention, there is provided a semiconductor device comprising: a semiconductor substrate that includes a first conductive layer, a second conductive layer on the first conductive layer, a first high density impurity area on the second conductive layer, and a second high density conductive impurity area on the first conductive impurity area; a trench in the semiconductor substrate having a depth not greater than that of the first conductive layer, relative to the second high density impurity area; a gate insulating layer on an inner wall of the trench; a polysilicon layer on the gate insulating layer; and a metal layer on the polysilicon layer in the trench, in which the metal layer fills the trench.

In order to further accomplish the object(s) of the present invention, there is provided a method for fabricating a semiconductor device, the method comprising: sequentially forming a first conductive layer, a second conductive layer, a first high density impurity area, and a second high density conductive impurity area in a semiconductor substrate; forming a trench exposing the first conductive layer; sequentially forming a gate insulating layer and a polysilicon layer on the semiconductor substrate including in the trench, and forming a nitride layer on the polysilicon layer, filling the trench; exposing the second high density impurity area in the semiconductor substrate by polishing, and removing the nitride layer in the trench; and depositing a metal layer on the substrate including an inner space of the trench, and removing the metal layer from outside the trench so that the metal layer remains on the polysilicon layer in the trench.

### BRIEF DESCRIPTION OF THE DRAWINGS

FIG. 1 is a cross-sectional view showing a device after a trench is formed according to an exemplary embodiment of the present method;

FIG. 2 is a cross-sectional view showing a device after a polysilicon layer is formed according to an exemplary embodiment of the present invention;

FIG. 3 is a cross-sectional view showing a device after a nitride layer is formed according to an exemplary embodiment of the present invention;

FIG. 4 is a cross-sectional view showing a device after an insulating layer, a polysilicon layer and a nitride layer are polished according to an exemplary embodiment of the present invention;

FIG. 5 is a cross-sectional view showing a device after a barrier metal layer is formed according to an exemplary embodiment of the present invention;

FIG. 6 is a cross-sectional view showing a device after a metal layer is formed according to an exemplary embodiment of the present invention;

FIG. 7 is a cross-sectional view showing a device after a metal layer and a barrier metal layer are partially formed according to an exemplary embodiment of the present invention; and

FIG. 8 is a cross-sectional view showing a device after an interconnection process is performed according to an exemplary embodiment of the present invention.

### DETAILED DESCRIPTION OF THE EMBODIMENTS

Hereinafter, a semiconductor device and a fabricating method thereof according to various embodiments will be described with reference to the accompanying drawings. The semiconductor device according to one embodiment, for example, is a transistor.

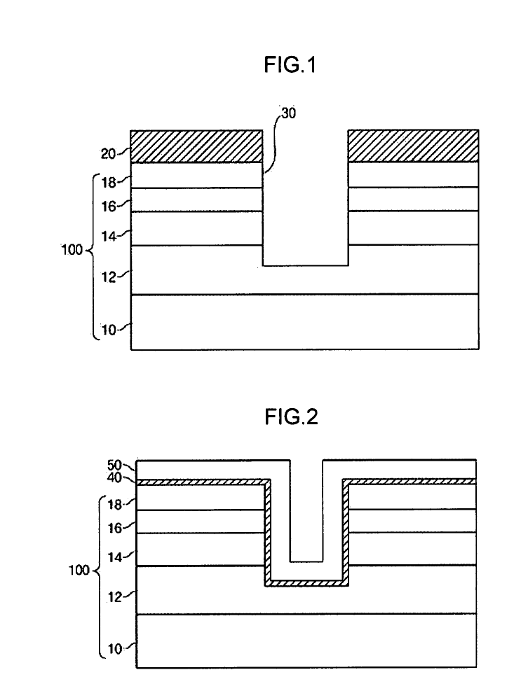

FIG. 1 is a cross-sectional view showing a device after a trench 30 is formed according to an exemplary embodiment of the present invention.

Referring to FIG. 1, an N-type epitaxial layer of silicon is formed on an N+ substrate 10 (generally by epitaxial growth), and is doped with boron (generally by ion implantation), thereby forming a P-type body diffusion layer 14 and a remaining N-type epitaxial layer 12. Then, a P+ high density impurity layer of silicon is formed on the P-type body diffusion layer 14 (generally by epitaxial growth), and is doped with As or P (generally by ion implantation), thereby forming an N+ source area 18 and a remaining P-type epitaxial layer 16.

Next, after forming a photoresist pattern 20 on the semiconductor substrate 100, which is formed as described above, in order to expose a portion in which a gate electrode is to be formed, the semiconductor substrate 100 is etched (generally by a Reactive Ion Etch (RIE) process) using the photoresist pattern 20 as a mask. In this way, the trench 30 is etched to a depth of at least the interface between the P-type body diffusion layer 14 and the N-type epitaxial layer 12) and the photoresist pattern 20 is removed. Although various (doped) silicon etch chemistries can be employed, since the layers 12-18 contain primarily crystalline silicon, a timed etch using a single etch chemistry (i.e., etching can be performed under a first predetermined set of etch conditions for a predetermined period of time sufficient to etch the trench, given the known thicknesses and rate of etching of layers 12-18, and the target depth of the trench) can be employed to form the trench. In various embodiments, the trench may have a target width of from about 90 nm to 350 nm, 110 nm to 250 nm, or any range of values therein.

FIG. 2 is a side sectional view showing the device after a polysilicon layer 50 is formed according to an exemplary embodiment of the present invention.

As shown in FIG. 2, a thermal oxide layer is formed on the entire surface of the semiconductor substrate 100 including the sidewalls of the trench 30 (generally by wet or dry thermal oxidation of silicon) as a gate insulating layer 40. Then, a polysilicon layer 50 is deposited on the gate insulating layer 40 as a conductive layer for a gate electrode. The polysilicon layer 50 is preferably deposited with a thickness of about 100 Å to 1000 Å, and such that a gap or space remains in the trench between opposing surfaces of the polysilicon layer 50. If the polysilicon layer 50 is thickly deposited, the thickness of a metal layer for the gate electrode is reduced, so that the gate conductive layer cannot have a desired resistance value. Preferably, the polysilicon layer 50 is deposited as thin as possible.

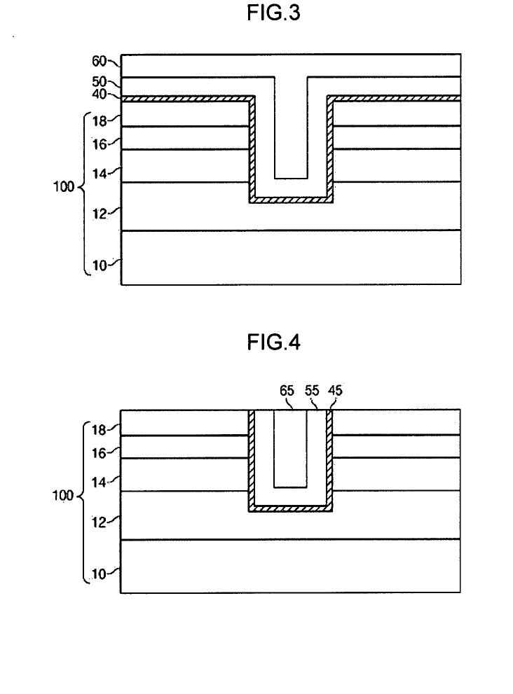

FIG. 3 is a cross-sectional view showing the device after a nitride layer 60 is formed according to an exemplary embodiment of the present invention.

As shown in FIG. 3, a sacrificial layer 60 is formed on the polysilicon layer 50. The sacrificial layer can comprise or consist essentially of any material that can be selectively etched relative to (poly)crystalline silicon and the gate insulating layer (e.g., silicon oxide), such as silicon nitride. The sacrificial (e.g., silicon nitride) layer 60 fills the remaining space of the trench 30 and is simultaneously formed on the entire surface of the polysilicon layer 50.

FIG. 4 is a cross-sectional view showing the device after the insulating layer 40, the polysilicon layer 50 and the nitride layer 60 are polished according to the an exemplary embodiment of the present invention. After forming the nitride layer 60, a Chemical Mechanical Polishing (CMP) process is performed such that the N+ source area 18 of the semiconductor substrate 100 is exposed. Accordingly, the insulating layer 40, the polysilicon layer 50 and the nitride layer 60 are removed from the surface of the semiconductor substrate 100. That is, the insulating layer 40, the polysilicon layer 50 and the nitride layer 60 remain in the trench 30 only. In one embodiment, the CMP step is performed for a predetermined period of time sufficient to remove the insulating layer 40, the polysilicon layer 50 and the nitride layer 60 over layer 18, given the known thicknesses and polishing rates of the insulating layer 40, the polysilicon layer 50 and the nitride layer 60. In an alternative embodiment, the chemistry of the CMP process changes at least once as a function of time (given the known thickness[es] and polishing rate[s] of the material[s] being polished), to improve polishing selectivity.

The insulating layer 40, the polysilicon layer 50 and the nitride layer 60 that remain in the trench 30 serve as a gate insulating layer pattern 45, a polysilicon layer pattern 55 and a nitride layer pattern 65, respectively. Thereafter, the nitride layer pattern 65 is removed through an etch process (generally by wet etching, such as with aqueous phosphoric acid at a temperature of 50-90° C.).

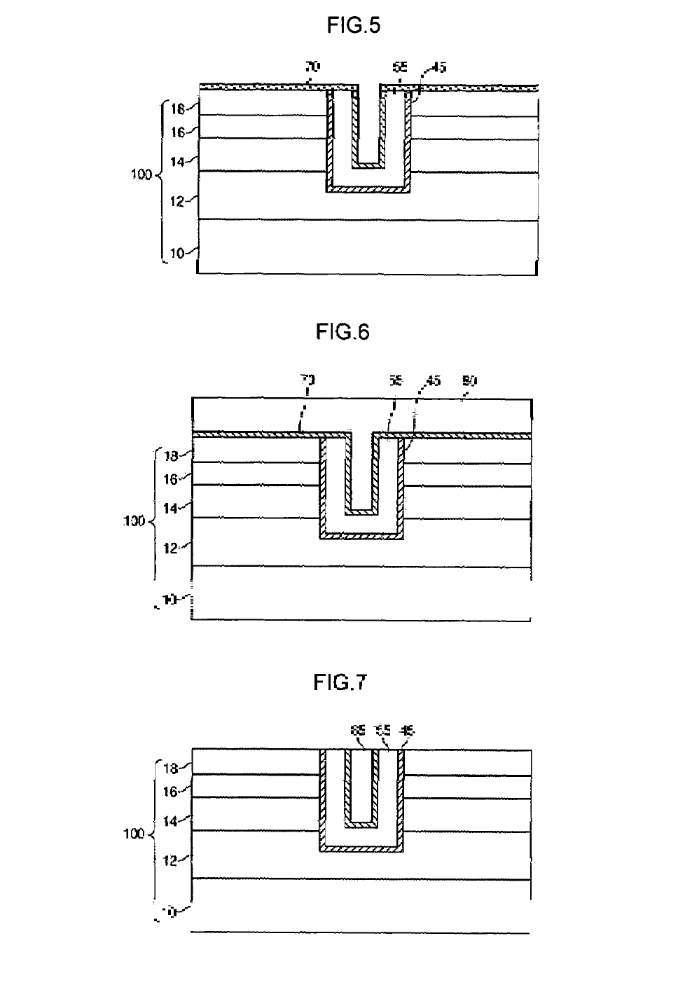

FIG. 5 is a cross-sectional view showing the device after a barrier metal layer 70 is formed according to a further exemplary embodiment of the present invention.

As shown in FIG. 5, a barrier metal layer 70 is formed on the entire surface of the semiconductor substrate 100, inclusive of the trench 30 (which has no nitride layer pattern 65 therein). The barrier metal layer 70 may comprise one or more of Ta, TaN, Ti or TiN (e.g., a Ta/TaN bilayer or a Ti/TiN bilayer). The barrier metal layer 70 can be formed by depositing the one or more layers (generally, by sputtering and/or chemical vapor deposition [CVD]; for example, the elemental metal layers may be formed by sputtering, and the metal nitrides by CVD or sputtering in the presence of a nitrogen source, such as dinitrogen and/or ammonia).

FIG. 6 is an exemplary sectional view showing the device after a metal layer 80 is formed according to an exemplary embodiment of the present invention.

As shown in FIG. 6, a metal layer 80 is formed on the barrier metal layer 70. The metal layer 80 fills the inner space of the trench 30 and is simultaneously formed on the entire surface of the semiconductor substrate 100. For example, the metal layer 80 can be formed by depositing Al (generally by sputtering).

FIG. 7 is a cross-sectional view showing the device after the metal layer 80 and the barrier metal layer 70 are partially formed according to an exemplary embodiment of the present invention.

As shown in FIG. 7, an etch back process is performed for the metal layer 80, thereby removing the metal layer 80 and the barrier metal layer 70 from the surface of the semiconductor substrate 100. Alternatively, the metal layer 80 and the barrier metal layer 70 may be removed by CMP. Accordingly, the metal layer 80 and the barrier metal layer 70 remain in the trench only, and the metal layer 80 buried in the trench 30 serves as a metal layer 85. In one embodiment, an etchback process and a CMP process are performed, so that the metal layer 80 and the barrier metal layer 70 are planarized until the surface of the semiconductor substrate 100 is exposed, thereby forming the metal layer 85.

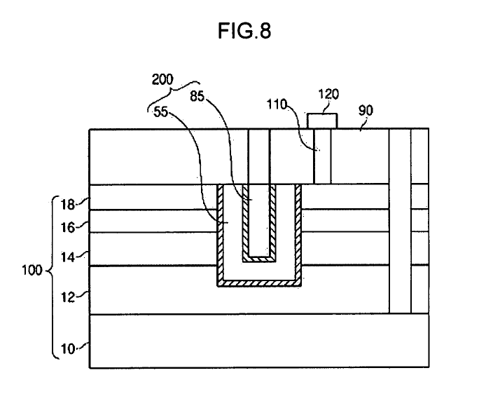

FIG. 8 is a cross-sectional view showing the device after an interconnection process is performed according to an exemplary embodiment of the present invention.

By performing the processes as described above, a gate electrode 200 including the polysilicon pattern 55 and the metal layer 85 is completed. As shown in FIG. 8, an Undoped Silicate Glass (USG) oxide layer or a High Doped Plasma (HDP) oxide layer is deposited on the entire surface of the semiconductor substrate 100 as an interlayer dielectric layer 90. Then, contact holes are etched in the interlayer dielectric layer 90 by a dry etching process using a contact mask (photolithography), thereby forming contact holes that exposes the metal layer 85 of the gate electrode 200, the N+ source area 18 and the N+ substrate 10 (drain area).

After forming the contact holes, the contact holes are filled with doped polysilicon or metal (e.g., tungsten or aluminum, with one or more optional barrier layers as described above) as a conductive layer, thereby forming a contact 110. Then, an interconnection process (e.g., metal deposition and photolithography) is performed to form an interconnection 120 (e.g., aluminum) connected to the contact 110. Alternatively, a trench can be formed in dielectric layer 90 in accordance with known “dual damascene” metallization techniques, and copper metallization and contacts can be formed to the gate electrode 200, the N+ source area 18 and the N+ substrate 10 (drain area).

According to the embodiments as described above, a trench is formed in the substrate, and a gate electrode that has a stacked structure comprising a polysilicon layer and a metal layer is formed in the trench, thereby allowing the gate electrode to have low surface resistance. That is, the gate electrode is believed to have low surface resistance by virtue of the metal layer, and the operation of the device can be controlled by the polysilicon layer being in contact with the gate insulating layer. As a result, a high performance transistor and/or word line having an improved driving speed can be fabricated.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a semiconductor substrate having a first conductive layer, a second conductive layer on the first conductive layer, a first high density impurity area on the second conductive layer, and a second high density impurity area on the first high density conductive impurity area;
a trench in the semiconductor substrate having a depth not greater than that of the first conductive layer relative to the second high density impurity area;
a gate insulating layer on an inner wall of the trench;
a polysilicon layer on the gate insulating layer in the trench; and
a metal layer on the polysilicon layer in the trench, in which the metal layer fills the trench.

2. The semiconductor device as claimed in claim 1, wherein the gate insulating layer includes a thermal oxide layer.

3. The semiconductor device as claimed in claim 1, wherein the polysilicon layer has a thickness of 10 Å to 1000 Å.

4. The semiconductor device as claimed in claim 1, further comprising a barrier metal layer between the polysilicon layer and the metal layer.

5. The semiconductor device as claimed in claim 4, wherein the barrier metal layer includes at least one member selected from the group consisting of Ta, TaN, Ti and TiN.

6. The semiconductor device as claimed in claim 1, wherein the metal layer includes an aluminum layer.

7. The semiconductor device as claimed in claim 1, further comprising a contact connected to the metal layer, and an insulating layer having an interconnection connected to the contact.

8. The semiconductor device as claimed in claim 1, wherein the first conductive layer includes an N-type epitaxial layer, and the second conductive layer includes a P-type body layer.

9. The semiconductor device as claimed in claim 1, wherein the first high density impurity area includes a P+ high density impurity layer, and the second high density impurity area includes an N+ source area.

10. A method for fabricating a semiconductor device, the method comprising:
sequentially forming a first conductive layer, a second conductive layer, a first high density impurity area, and a second high density impurity area on a semiconductor substrate;
forming a trench exposing the first conductive layer;
sequentially forming a gate insulating layer and a polysilicon layer on the semiconductor substrate including in the trench, and forming a sacrificial layer on the polysilicon layer, filling the trench;
polishing to expose the second high density impurity area in the semiconductor substrate, and removing the sacrificial layer in the trench; and
depositing a metal layer on the substrate including an inner space of the trench, and removing the metal layer from outside the trench so that the metal layer remains on the polysilicon layer in the trench.

11. The method as claimed in claim 10, wherein removing the metal layer from outside the trench comprises an etch back process.

12. The method as claimed in claim 10, wherein the gate insulating layer includes a thermal oxide layer.

13. The method as claimed in claim 10, wherein the polysilicon layer has a thickness of 100 Å to 1000 Å.

14. The method as claimed in claim 10, further comprising forming a barrier metal layer in an area of the trench which includes the polysilicon layer, after removing the sacrificial layer.

15. The method as claimed in claim 14, wherein the barrier metal layer includes at least one member selected from the group consisting of Ta, TaN, Ti and TiN.

16. The method as claimed in claim 10, wherein the metal layer includes an aluminum layer.

17. The method as claimed in claim 10, further comprising:
forming a dielectric layer on the second high density impurity area after forming the metal layer;
etching the dielectric layer to form a contact hole that exposes at least one of the metal layer, the first high density impurity area, and the semiconductor substrate;
forming a contact by filling the contact hole with doped silicon or metal; and
forming an interconnection connected to the contact.

18. The method as claimed in claim 17, wherein forming the dielectric layer comprises depositing an Undoped Silicate Glass (USG) oxide layer or a High Doped Plasma (HDP) oxide layer on the second high density impurity area.

19. The method as claimed in claim 10, wherein the sacrificial layer comprises silicon nitride.
